(19) United States
(12) Patent Application Publication
(10) Pub. No.: US 2023/0335595 A1
(43) Pub. Date: Oct. 19, 2023

(54) SILICON CARBIDE SEMICONDUCTOR POWER TRANSISTOR AND METHOD OF MANUFACTURING THE SAME

(71) Applicant: LEAP Semiconductor Corp., Taoyuan City (TW)

(72) Inventors: Wei-Fan Chen, Taichung City (TW); Kuo-Chi Tsai, Taoyuan City (TW)

(73) Assignee: LEAP Semiconductor Corp., Taoyuan City (TW)

(21) Appl. No.: 17/719,403

(22) Filed: Apr. 13, 2022

(51) Int. Cl. H01L 29/16; H01L 29/66; H01L 29/739

(52) U.S. Cl. CPC H01L 29/1608; H01L 29/66325; H01L 29/7393

(57) ABSTRACT

A silicon carbide semiconductor power transistor includes a substrate made of SiC, a drift layer on a plane of the substrate, well regions in the drift layer, source regions within the well regions, gates on the drift layer, a gate insulation layer between the drift layer and each of the gates, and well pick-up regions in the drift layer. V-grooves are formed in the drift layer, and a bottom and sidewalls of each of the V-grooves is surround by each of the well regions. The bottom of each of the V-grooves is in direct contact with each of the source regions. The gates are between the V-grooves and extend to the sidewalls of the V-grooves on both sides thereof. The well pick-up regions are below the bottom of each of the V-grooves, and each of the well pick-up regions passes through the source regions and contacts with the well regions.

### BACKGROUND

### Technical Field

The disclosure relates to a silicon carbide semiconductor power transistor, and particularly relates to a silicon carbide semiconductor power transistor and a method of manufacturing the same.

### Description of Related Art

High voltage, field effect transistors, also known as power transistors or silicon carbide semiconductor power transistors, are well known in the semiconductor arts. Vertical power transistor including an extended drain or drift region can support the applied high voltage when the device is in the “off” state, and this type power transistor are commonly used in power conversion applications such as AC/DC converters for offline power supplies, motor controls, and so on. These power transistor devices can be switched at high voltages and achieve a high blocking voltage in the “off” state while minimizing the resistance to current flow between the drain and the source, often referred to as the specific on resistance (Rₒₙ), in the “on” state.

Silicon carbide (SiC) MOSFETs are highly noticed due to their superior physical properties over silicon-based devices of the same device area. For example, SiC MOSFETs are known to exhibit higher blocking voltage, lower Rₒₙ, and higher thermal conductivity as compared to silicon MOSFETs.

4H-SiC MOSFETs are promising building blocks for low loss and high voltage switching power modules. One of the key challenges for 4H-SiC power MOSFETs is to achieve both low specific on-resistance and high threshold voltage at the same time. This is because the nitridation process, which is generally used after gate oxidation in order to reduce the channel resistance, typically ends up with a lower threshold voltage rather than high channel mobility. A 4H-SiC V-grooves MOSFET device with (03-38) orientation channel has been researched to overcome above problems.

However, since high breakdown voltage requirement of the V-grooves MOSFETs, the p-well doping concentration as well as the p-well junction depth in the V-groove MOSFETs are not easy to control, it suffers from low breakdown voltage due to short channel effect of traditional V-groove MOSFETs.

### SUMMARY

The disclosure provides a silicon carbide semiconductor power transistor for solving the short channel effect problem of the prior research.

The disclosure further provides a method of manufacturing a silicon carbide semiconductor power transistor to reduce the influence of short channel effect without complicated processing steps.

The silicon carbide semiconductor power transistor of the disclosure includes a substrate made of silicon carbide (SiC), a drift layer disposed on a plane of the substrate, a plurality of well regions disposed in the drift layer, a plurality of source regions disposed within the well regions, a plurality of gates disposed on the drift layer, a gate insulation layer disposed between the drift layer and each of the gates, and a plurality of well pick-up regions disposed in the drift layer. A plurality of V-grooves is formed in the drift layer, and the V-grooves are parallel to each other. A bottom and sidewalls of each of the V-grooves are surrounded by each of the well regions, and the bottom of each of the V-grooves are in direct contact with each of the source regions. The gates are disposed between the V-grooves and extend to the sidewalls of the V-grooves on both sides of each gates. The well pick-up regions are disposed below the bottom of each of the V-grooves, and each of the well pick-up regions pass through the source region and contact with the well region.

In an embodiment of the disclosure, the plane of the substrate is one of {1000} orientation planes, one of {1100} orientation planes, or one of {11-20} orientation planes.

In an embodiment of the disclosure, the plane of the substrate has an off-axis orientation equal to 5° or less to one of the {1000} orientation planes, the {1100} orientation planes, and the {11-20} orientation planes.

In an embodiment of the disclosure, a channel region of the silicon carbide semiconductor power transistor was formed in the sidewall, an orientation plane of the channel region is (03-38) plane, and a tilt angle between the sidewall of each of the V-grooves and the plane of the substrate is 54.7°.

In an embodiment of the disclosure, the substrate, the drift layer, and the source regions have a first conductive type, and the well region and the well pick-up regions have a second conductive type.

In an embodiment of the disclosure, a doping concentration of the drift layer is ranged from 3E15/cm³ to 4E16/cm³.

In an embodiment of the disclosure, a doping concentration of the well region is ranged from 4.2E16/cm³ to 5.6E17/cm³.

In an embodiment of the disclosure, a doping concentration of the plurality of source regions is ranged from 5E17/cm³ to 5E19/cm³.

In an embodiment of the disclosure, a width of each of the well pick-up regions is from 0.2 μm to 1.0 μm.

In an embodiment of the disclosure, the bottom of each of the V-grooves has an area exposed from the gates, and a width of the area is from 1.0 μm to 2.0 μm.

In an embodiment of the disclosure, the silicon carbide semiconductor power transistor further includes source electrodes, gate electrodes and drain electrode. The source electrodes are disposed in the V-grooves of the drift layer to be in direct contact with the plurality of well pick-up regions and the plurality of source regions. The gate electrodes are disposed on the plurality of gates. The drain electrode is disposed on a back of the substrate.

The method of manufacturing the silicon carbide semiconductor power transistor includes forming a drift layer on an upper surface of a silicon carbide (SiC) substrate, and then forming a plurality of V-grooves in the drift layer. A plurality of well regions is formed in the drift layer and surrounds a bottom and sidewalls of each of the V-grooves. A plurality of source regions is formed within the well regions, wherein the bottom of each of the V-grooves are in direct contact with each of the source regions. A plurality of well pick-up regions is formed in the drift layer below the bottom of each of the V-grooves to pass through the source regions and contact with the well regions. A gate insulation layer is conformally formed on the drift layer and the bottom and the sidewalls of each of the V-grooves, and then a conductive layer is formed on the gate insulation layer. The conductive layer and the gate insulation layer are etched to form a portion of the gates and expose the bottom of each of the V-grooves.

In another embodiment of the disclosure, after forming the plurality of gates, the method further includes forming a plurality of source electrodes and a plurality of gate electrodes, wherein the source electrodes are disposed in the V-grooves to be in direct contact with the well pick-up regions and the source regions at the exposed bottom of each of the V-grooves, and the gate electrodes are disposed on the plurality of gates between the V-grooves.

In another embodiment of the disclosure, the method further includes forming a drain electrode on a bottom surface of the SiC substrate.

In another embodiment of the disclosure, the upper surface of the SiC substrate is one of {1000} orientation planes, one of {1100} orientation planes, or one of {11-20} orientation planes.

In another embodiment of the disclosure, the upper surface of the SiC substrate has an off-axis orientation equal to 5° or less to one of the {1000} orientation planes, the {1100} orientation planes, and the {11-20} orientation planes.

In another embodiment of the disclosure, a channel region is formed in the sidewall, an orientation plane of the channel region is (03-38) plane, and the step of forming the plurality of V-grooves includes forming a tilt angle of 54.7° between the sidewall of each of the V-grooves and the upper surface of the SiC substrate.

Based on the above, according to the silicon carbide semiconductor power transistor of the disclosure, the source regions are formed in the drift layer below the bottom of each of the V-grooves, and they can be applied to the same potential as the source regions via the well pick-up regions. Therefore, the current flow path can be increased. Since the current flow path is extended, the doping concentration of the well region can be high enough to reduce the channel length, the specific on resistance (Rₒₙ) is reduced accordingly, while the threshold voltage can be kept at the same time.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional view of a silicon carbide semiconductor power transistor according to a first embodiment of the disclosure.

FIG. 2 shows the silicon carbide semiconductor power transistor of FIG. 1 in the on state.

FIGS. 3A to 3K are cross-sectional views illustrating steps of a method of manufacturing a silicon carbide semiconductor power transistor according to a second embodiment of the disclosure.

### DESCRIPTION OF THE EMBODIMENTS

With reference to the drawings attached, the disclosure will be described by means of the embodiments below. Nevertheless, the disclosure may be embodied in many different forms and should not be construed as limited to the embodiments set forth herein. In the drawings, for the purpose of clarity and specificity, the sizes and the relative sizes of each layer and region may not be illustrated in accurate proportion.

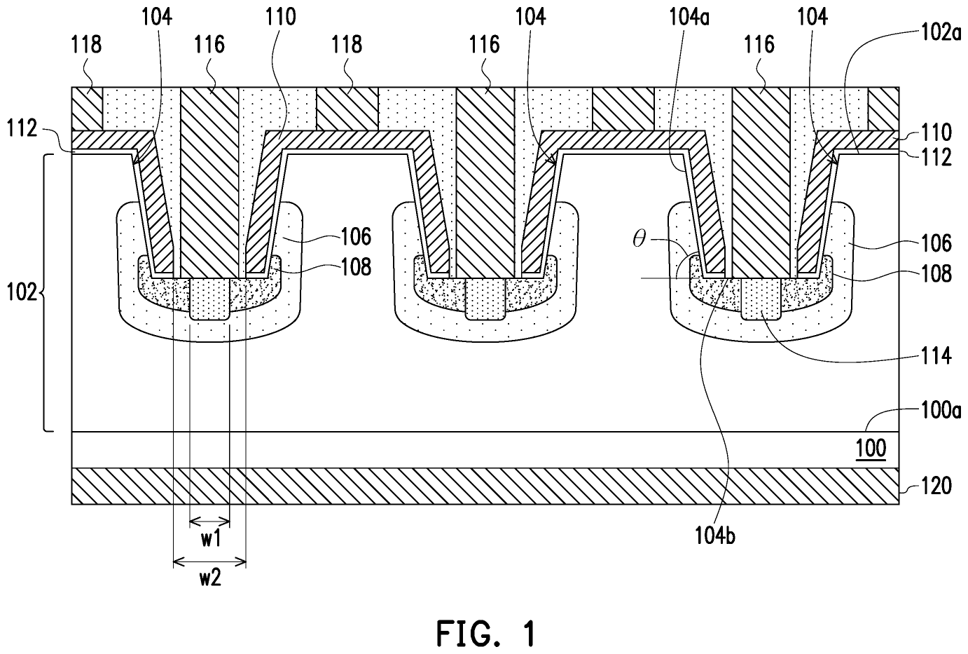

FIG. 1 is a cross-sectional view of a silicon carbide semiconductor power transistor according to a first embodiment of the disclosure.

Referring to FIG. 1, the silicon carbide semiconductor power transistor of the first embodiment includes at least a substrate 100 made of silicon carbide (SiC), a drift layer 102 with a plurality of V-grooves 104 formed therein, a plurality of well regions 106 disposed in the drift layer 102, a plurality of source regions 108 disposed within the well regions 106, a plurality of gates 110 disposed on the drift layer 102, a gate insulation layer 112 disposed between the drift layer 102 and each of the gates 110, and a plurality of well pick-up regions 114 disposed in the drift layer 102. The drift layer 102 is disposed on a plane 100a of the substrate 100. In one embodiment, the plane 100a of the substrate 100 is (1000) orientation plane, and it is helpful to form the transistor with improved channel mobility and high weak inversion threshold in the (03-38) crystal plane. In another embodiment, the plane 100a of the substrate 100 can be one of {1100} orientation planes or one of {11-20} orientation planes. A channel region of the silicon carbide semiconductor power transistor is formed in the sidewall 104a of each of the V-grooves 104, and an orientation plane of the channel region is (03-38) plane. The (03-38) plane of the channel region represents the face tilted by 54.7° toward the direction from the (1000) orientation plane and tilted by 35.3° toward the direction from the (11-20) orientation plane. Moreover, the plane 100a of the substrate 100 has an off-axis orientation equal to 5° or less to one of the{1000} orientation planes, one of the{1100} orientation planes, or one of the {11-20} orientation planes, preferably, 3° or less to one of the{1000} orientation planes, one of the {1100} orientation planes, or one of the {11-20} orientation planes.

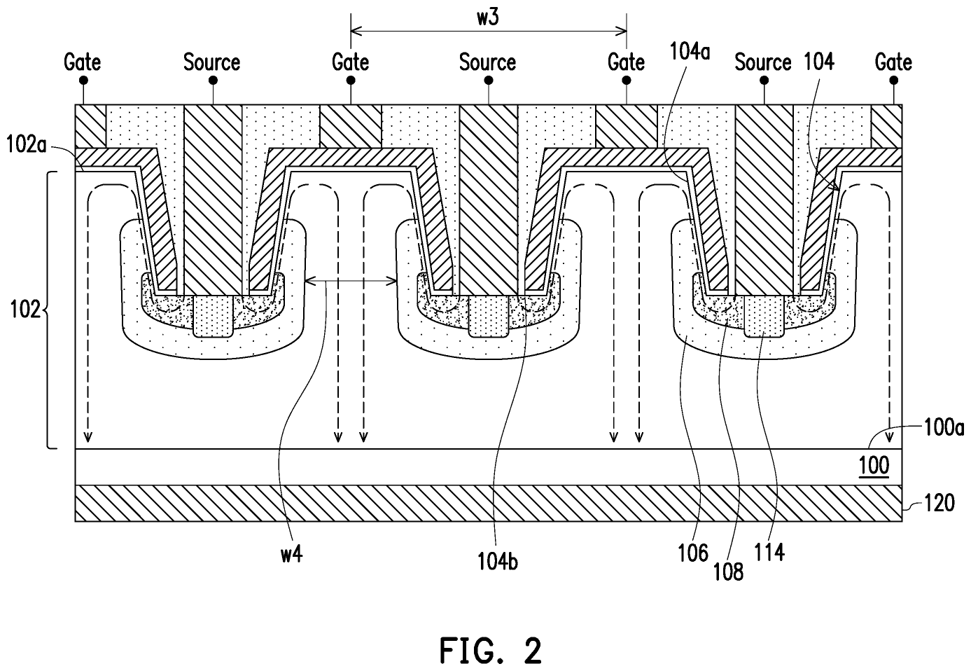

Referring to FIG. 1 again, the V-grooves 104 are parallel to each other, wherein a tilt angle θ between a sidewall 104a and a bottom 104b of each of the V-grooves 104 is, for example, 54.7° in (1000) substrate's device. The bottom 104b and the sidewalls 104a of each of the V-grooves 104 are surrounded by each of the well regions 106, and the bottom 104b of each of the V-grooves 104 is in direct contact with each of the source regions 108. The gates 110 are disposed between the V-grooves 104 and extend to the sidewalls 104a of the V-grooves 104 on both sides of each gates 110. For example, the gates 110 are polysilicon and conformally deposited on the sidewall 104a and the top 102a of the drift layer 102, and the thickness of the gate insulation layer 112 is, for instance, ranged from 300 Å to 1,200 Å. The well pick-up regions 114 are disposed below the bottom 104b of each of the V-grooves 104, and each of the well pick-up regions 114 passes through the source region 108 and contacts with the well region 106. Accordingly, the well regions 106 are applied to the same potential as the source regions 108, and thus the current flow path can be increased as shown in FIG. 2.

FIG. 2 shows the silicon carbide semiconductor power transistor of FIG. 1 in the on state, wherein some reference symbols and labeled representations are omitted to clear the electrical property in the silicon carbide semiconductor power transistor. In FIG. 2, the current flow paths (shown by the dotted line) are from the bottom 104b of the V-groove 104 upward along the sidewall 104a and then from the top 102a of the drift layer 102 down to the substrate 100 and the drain electrode 120. In other words, since the current flow paths are extended, as well as the well region 106 in the bottom 104b of the disclosure, the drawback of snapback effect of MOSFET can be eliminated while maintaining specific on resistance (Rₒₙ) and the threshold voltage.

In the first embodiment, the doping concentration of the drift layer 102 is ranged from 3E15/cm³ to 4E16/cm³, the doping concentration of the well region 106 is ranged from 4.2E16/cm³ to 5.6E17/cm³, and the doping concentration of the plurality of source regions 108 is ranged from 5E17/cm³ to 5E19/cm³. However, the disclosure is not limited herein. The doping concentrations of the drift layer 102, the well region 106, and the source regions 108 may be modified as per the desired design. Moreover, the doping concentration of the well pick-up regions 114 is 5E18/cm³ to 2E20/cm³, for instance.

Referring to FIG. 1, the substrate 100, the drift layer 102, and the source regions 108 have a first conductive type; and the well region 106 and the well pick-up regions 114 have a second conductive type. For example, the substrate 100, the drift layer 102, and the source regions 108 are N type, and the well region 106 and the well pick-up regions 114 are P type. In one embodiment, a width w1 of each of the well pick-up regions 114 is from 0.2 μm to 1.0 μm, for instance. In one embodiment, the bottom 104b of each of the V-grooves 104 has an area exposed from the gates 110, and a width w2 of the area is from 1.0 μm to 2.0 μm, for instance. The term “width” refers to the distance between two sides of the region (e.g. the well pick-up regions 114 or the exposed area of the bottom 104b) in the cross-sectional view of the substrate 100. In the first embodiment, the silicon carbide semiconductor power transistor further includes source electrodes 116, gate electrodes 118, and drain electrode 120. The source electrodes 116 are disposed in the V-grooves 104 of the drift layer 102 to be in direct contact with the well pick-up regions 114 and the source regions 108. The gate electrodes 118 are disposed on the gates 110. The drain electrode 120 is disposed on a back 100b of the substrate 100.

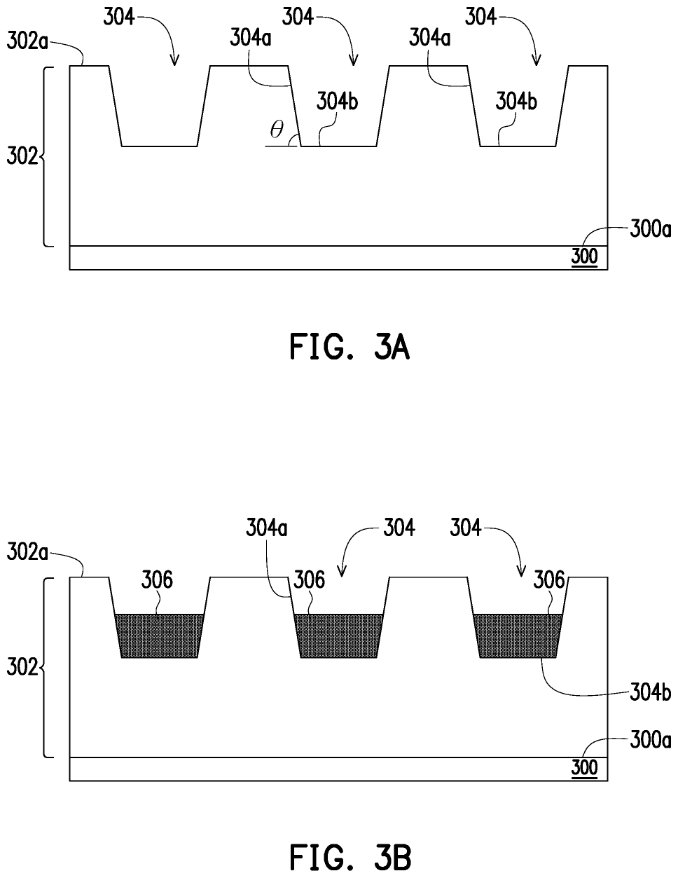

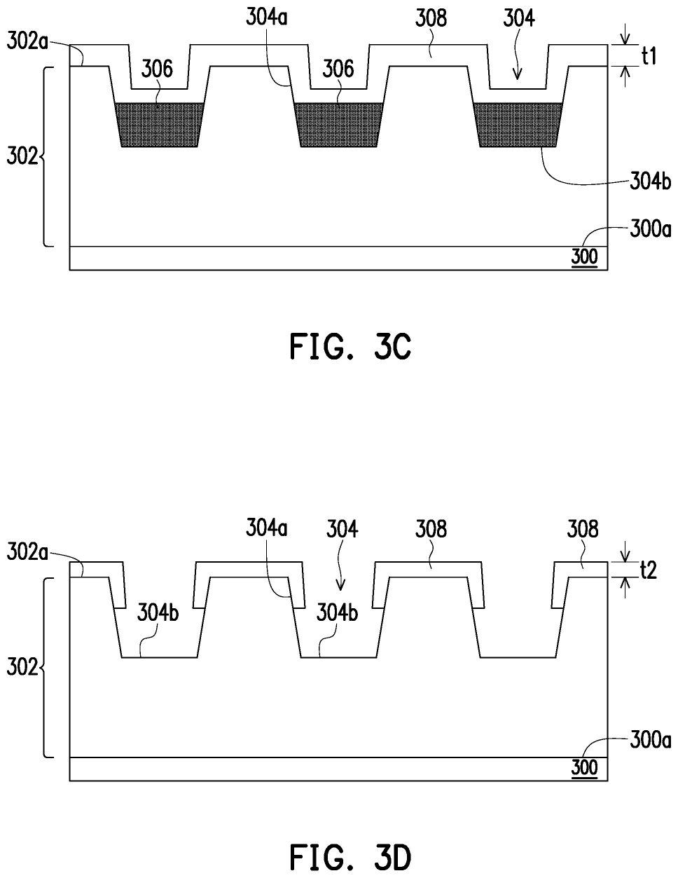

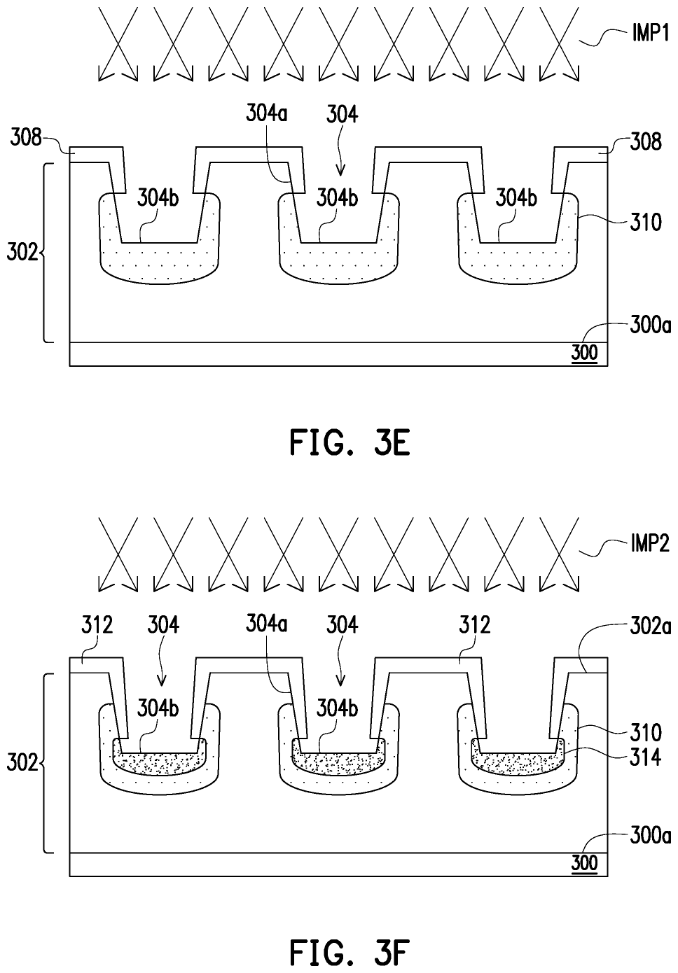

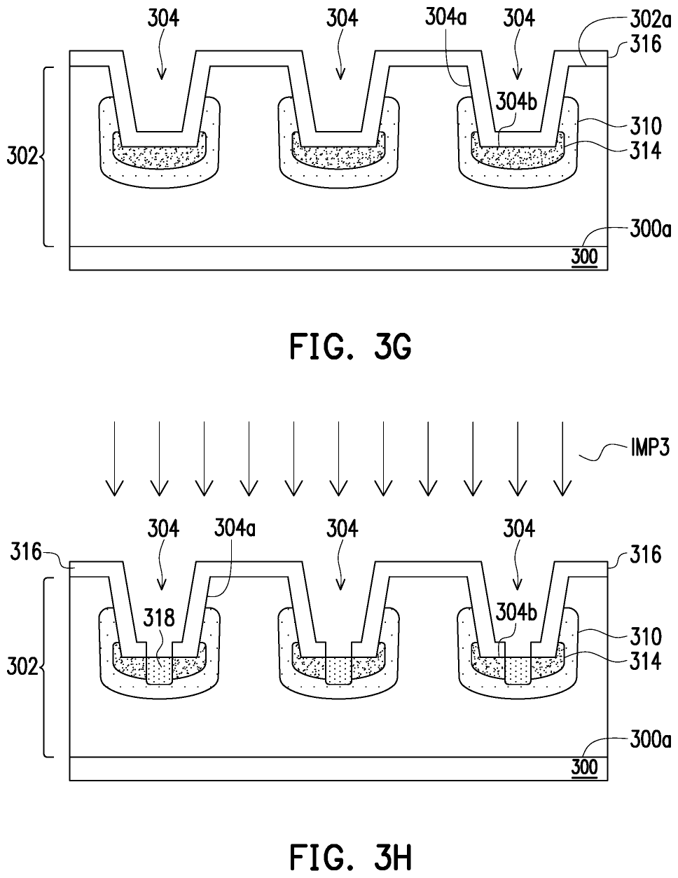

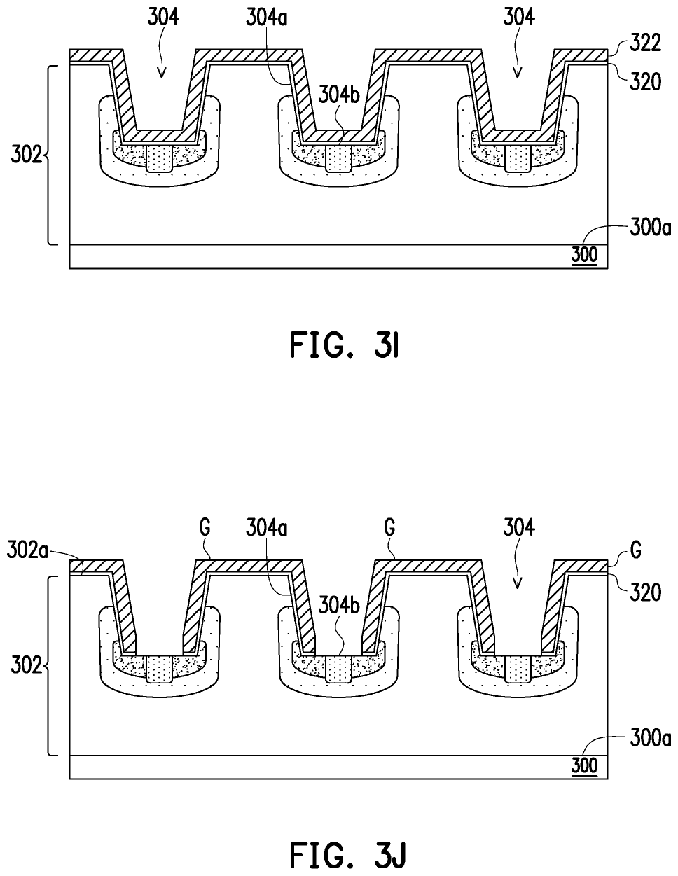

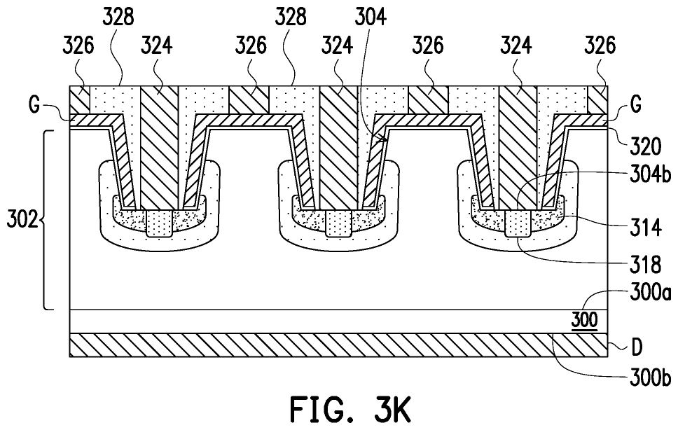

FIGS. 3A to 3K are cross-sectional views illustrating steps of a method of manufacturing a silicon carbide semiconductor power transistor according to a second embodiment of the disclosure.

Referring to FIG. 3A, a silicon carbide (SiC) substrate 300 is utilized, and the SiC substrate 300 may be an n type substrate. A drift layer 302 is formed on an upper surface 300a of the SiC substrate 300, and the drift layer 302 may be an N-drift layer, wherein the doping concentration of the drift layer 302 is ranged from 3E15/cm³ to 4E16/cm³, for instance. However, the disclosure is not limited herein. The upper surface 300a of the SiC substrate 300 may be one of the {1000} orientation planes, and it is helpful to form the transistor with improved channel mobility and high weak inversion threshold in the (03-38) crystal plane. In another embodiment, the upper surface 300a of the SiC substrate 300 can be one of the {1100} orientation planes or one of the {11-20} orientation planes. Thereafter, a plurality of V-grooves 304 is formed in the drift layer 302, and a channel region is formed in the sidewall 304a of each of the V-grooves 304, and an orientation plane of the channel region is (03-38) plane. The (03-38) plane of the channel region represents the face tilted by 54.7° toward the direction from the (1000) plane and tilted by 35.3° toward the direction from the (1100) plane if (1100) SiC substrate are used for device. The upper surface 300a of the SiC substrate 300 has an off-axis orientation equal to 5° or less to one of the{1000} orientation planes, one of the{1100} orientation planes, or one of the {11-20} orientation planes. The step of forming the V-grooves 304 may include forming a patterned SiO₂ hard mask (not shown) on the top 302a of the drift layer 302, and then performing the thermochemical self-organized etching process in Cl₂ ambient by using the patterned SiO₂ hard mask as etching mask, wherein a tilt angle θ of 54.7° may be formed between a sidewall 304a and the bottom 304b of each of the V-grooves 304 during the etching.

Then, referring to FIG. 3B, in order to form well regions, a coating layer 306 may be formed in the V-grooves 304, and the step of forming the coating layer 306 may include entirely coating a material on the substrate 300 to fill in the V-grooves 304, and then etch back the material until the top 302a and a portion of the sidewall 304a are exposed.

Thereafter, referring to FIG. 3C, a first mask layer 308 is conformally deposited on the top 302a of the drift layer 302, the sidewall 304a of the V-grooves, and the coating layer 306.

From the perspective of simplifying process, the thickness t1 of the first mask layer 308 on the top 302a is preferably thicker than that of the first mask layer 308 on the coating layer 306, and it can be accomplished by varying the process conditions.

Then, referring to FIG. 3D, the first mask layer 308 is etched back until the coating layer 306 is exposed, and then the coating layer 306 is removed. Since the thickness t1 of the first mask layer 308 on the top 302a is thicker than that of the first mask layer 308 on the coating layer 306 as shown in FIG. 3C, the first mask layer 308 can be kept on the top 302a and the sidewall 304a even if the thickness t2 is thinned after etching back the first mask layer 308.

After that, referring to FIG. 3E, a tilt implantation IMP1 is performed on the drift layer 302 to form a plurality of well regions 310 in the drift layer 302 and surrounding the bottom 304b and the sidewalls 304a of each of the V-grooves 304. In one embodiment, the tilt implantation IMP1 may include high tilt implantation and low tilt implantation. The well regions 310 may be p-type wells, and the doping concentration of the well region 106 is ranged from 4.2E16/cm³ to 5.6E17/cm³, for instance.

Then, referring to FIG. 3F, the first mask layer 308 is first removed, and then a second mask layer 312 is formed. The step of forming the second mask layer 312 are the same as that of forming the first mask layer 308, and will not be repeated herein. Another tilt implantation IMP2 is then performed on the drift layer 302 to form a plurality of source regions 314 within the well regions 310, wherein the bottom 304b of each of the V-grooves 304 is in direct contact with each of the source regions 314. In one embodiment, the tilt implantation IMP2 may include high tilt implantation and low tilt implantation. The source regions 314 may be N+ regions, and the doping concentration of the plurality of source regions 108 is ranged from 5E17/cm³ to 5E19/cm³, for instance.

Thereafter, referring to FIG. 3G, the second mask layer 312 is first removed, and then a third mask layer 316 is formed. The third mask layer 316 is conformally deposited on the top 302a of the drift layer 302, the sidewall 304a and the bottom 304b of each of the V-grooves 304.

Then, referring to FIG. 3H, the third mask layer 316 is patterned to expose a potion of the bottom 304b of each of the V-grooves 304. An ion implantation IMP3 is performed on the drift layer 302 to form a plurality of well pick-up regions 318 in the drift layer 302 below the bottom 304b of each of the V-grooves 304, and the well pick-up region 318 passes through the source region 314 and contact with the well region 310. The well pick-up regions 318 may be P+ region, and the doping concentration of the well pick-up regions 318 is ranged from 5E18/cm³ to 2E20/cm³, for instance.

Thereafter, referring to FIG. 3I, the third mask layer 316 is first removed, and then a gate insulation layer 320 is conformally formed on the drift layer 302 and the bottom 304b and the sidewalls 304a of each of the V-grooves 304. The gate insulation layer 320 may be a gate oxide with a thickness ranged from 300 Å to 1,200 Å. A conductive layer 322 is formed on the on the gate insulation layer 320, wherein the conductive layer 322 is, for example, a polysilicon layer.

After that, referring to FIG. 3J, the conductive layer 322 and the gate insulation layer 320 are etched to form a plurality of gates G on the gate insulation layer 320 and expose the bottom 304b of each of the V-grooves 304. The method of forming the gate G may include performing an anisotropic etching on the conductive layer 322 and the gate insulation layer 320 using a patterned photoresist (not shown) covering the top 302a of the drift layer 302 and the sidewall 304a of each the V-grooves 304.

Last, referring to FIG. 3K, source electrodes 324 and gate electrodes 326 are formed together. The source electrodes 324 are disposed in the V-grooves 304 to be in direct contact with the well pick-up regions 318 and the source regions 314 at the exposed bottom 304b of each of the V-grooves 304, and the gate electrodes 326 are disposed on the plurality of gates G between the V-grooves 304. The method of forming the source electrodes 324 and the gate electrodes 326 may include forming an insulation layer 328 on the top 302a of the drift layer 302, etching the insulation layer 328 to form openings exposing the well pick-up regions 318, the source region 314, and the gates G respectively, and depositing conductive material (e.g. metal or alloy) in the openings. After forming the source electrodes 324 and the gate electrodes 326, a drain electrode D is formed on a bottom surface 300b of the SiC substrate 300.

In summary, according to the silicon carbide semiconductor power transistor of the disclosure, the V-grooves are formed in the drift layer, and the well regions and the source regions are both formed below the V-grooves, and the well pick-up regions are formed to make the well regions and the source regions having equal potential; therefore, the current flow path from source to drain can be increased. If the current flow path is increased, the doping concentration of the well region can be high enough to reduce the specific on resistance (Rₒₙ) without lowering the threshold voltage.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A silicon carbide semiconductor power transistor, comprising:
a substrate made of silicon carbide (SiC);
a drift layer disposed on a plane of the substrate, wherein a plurality of V-grooves is formed in the drift layer, and the V-grooves are parallel to each other;
a plurality of well regions disposed in the drift layer, wherein a bottom and sidewalls of each of the V-grooves is surround by each of the well regions;
a plurality of source regions disposed within the well regions, wherein the bottom of each of the V-grooves is in direct contact with each of the source regions;
a plurality of gates disposed on the drift layer between the V-grooves, wherein each of the gates extend to the sidewalls of the V-grooves on both sides thereof;
a gate insulation layer disposed between the drift layer and each of the gates; and
a plurality of well pick-up regions disposed in the drift layer below the bottom of each of the V-grooves, and each of the well pick-up regions passes through the source region and contacts with the well region.

2. The silicon carbide semiconductor power transistor of claim 1, wherein the plane of the substrate is one of {1000} orientation planes, one of {1100} orientation planes, or one of {11-20} orientation planes.

3. The silicon carbide semiconductor power transistor of claim 2, wherein the plane of the substrate has an off-axis orientation equal to 5° or less to one of the {1000} orientation planes, the {1100} orientation planes, and the {11-20} orientation planes.

4. The silicon carbide semiconductor power transistor of claim 3, wherein a channel region is formed in the sidewall, an orientation plane of the channel region is (03-38) plane, and a tilt angle between the sidewall of each of the V-grooves and the plane of the substrate is 54.7°.

5. The silicon carbide semiconductor power transistor of claim 1, wherein the substrate, the drift layer, and the source regions have a first conductive type, and the well region and the well pick-up regions have a second conductive type.

6. The silicon carbide semiconductor power transistor of claim 1, wherein a doping concentration of the drift layer is ranged from 3E15/cm³ to 4E16/cm³.

7. The silicon carbide semiconductor power transistor of claim 1, wherein a doping concentration of the well region is ranged from 4.2E16/cm³ to 5.6E17/cm³.

8. The silicon carbide semiconductor power transistor of claim 1, wherein a doping concentration of the plurality of source regions is ranged from 5E17/cm³ to 5E19/cm³.

9. The silicon carbide semiconductor power transistor of claim 1, wherein a width of each of the well pick-up regions is from 0.2 μm to 1.0 μm.

10. The silicon carbide semiconductor power transistor of claim 1, wherein the bottom of each of the V-grooves has an area exposed from the gates, and a width of the area is from 1.0 μm to 2.0 μm.

11. The silicon carbide semiconductor power transistor of claim 1, further comprising:
a plurality of source electrodes disposed in the V-grooves of the drift layer to be in direct contact with the plurality of well pick-up regions and the plurality of source regions;
a plurality of gate electrodes disposed on the plurality of gates; and
a drain electrode disposed on a back of the substrate.

12. A method of manufacturing a silicon carbide semiconductor power transistor, comprising:
forming a drift layer on an upper surface of a silicon carbide (SiC) substrate;
forming a plurality of V-grooves in the drift layer;
forming a plurality of well regions in the drift layer and surrounding a bottom and sidewalls of each of the V-grooves;
forming a plurality of source regions within the well regions, wherein the bottom of each of the V-grooves is in direct contact with each of the source regions;
forming a plurality of well pick-up regions in the drift layer below the bottom of each of the V-grooves to pass through the source regions and contact with the well regions;
forming a gate insulation layer conformally on the drift layer and the bottom and the sidewalls of each of the V-grooves;
forming a conductive layer on the gate insulation layer; and
etching the conductive layer and the gate insulation layer to form a plurality of gates and expose the bottom of each of the V-grooves.

13. The method of manufacturing a silicon carbide semiconductor power transistor of claim 12, wherein after forming the plurality of gates, further comprising: forming a plurality of source electrodes and a plurality of gate electrodes, the source electrodes are disposed in the V-grooves to be in direct contact with the well pick-up regions and the source regions at the exposed bottom of each of the V-grooves, and the gate electrodes are disposed on the plurality of gates between the V-grooves.

14. The method of manufacturing a silicon carbide semiconductor power transistor of claim 12, further comprising: forming a drain electrode on a bottom surface of the SiC substrate.

15. The method of manufacturing a silicon carbide semiconductor power transistor of claim 12, wherein the upper surface of the SiC substrate is one of {1000} orientation planes, one of {1100} orientation planes, or one of {11-20} orientation planes.

16. The method of manufacturing a silicon carbide semiconductor power transistor of claim 15, wherein the upper surface of the SiC substrate has an off-axis orientation equal to 5° or less to one of the {1000} orientation planes, the {1100} orientation planes, and the {11-20} orientation planes.

17. The method of manufacturing a silicon carbide semiconductor power transistor of claim 12, wherein a channel region is formed in the sidewall, an orientation plane of the channel region is (03-38) plane, and the step of forming the plurality of V-grooves comprises forming a tilt angle of 54.7° between the sidewall of each of the V-grooves and the upper surface of the SiC substrate, and a channel region is formed in the sidewall.
